(19) United States
(12) Patent Application Publication
(10) Pub. No.: US 2002/0048379 A1
(43) Pub. Date: Apr. 25, 2002

(54) Guitar amplifier with volume control

(76) Inventor: Gunnar Flentje, Hamburg (DE)

Correspondence Address: GUNNAR FLENTJE, KIRCHENWEG 2, HAMBURG, 20099, DE

(21) Appl. No.: 09/982,887

(22) Filed: Oct. 22, 2001

Related U.S. Application Data
(60) Provisional application No. 60/242,228, filed on Oct. 23, 2000.

(51) Int. Cl. H03G 3/00; H03F 21/00

(52) U.S. Cl. 381/104; 381/120

(57) ABSTRACT

A musician's amplifier that produces an overdriven amplifier sound at any desired listening level by including a frequency-sensitive circuit for controlling power delivered to an audio speaker to thus control volume output of the amplifier. The circuit comprises a ladder control network including a series resistor coupled to the speaker and a continuously tapped transformer coil. The coil has infinite multiple taps selectively coupled to the speaker via a variable controller for setting unlimited relative volume levels. The circuit maintains the input impedance seen by the driving source within a range close to a predetermined impedance comparable to a conventional speaker impedance. It is interposed between the output of the power amplifier and the loudspeaker and also maintains a constant proportional quality of high frequencies in the amplified signal at any volume level. The pre-amplifier section and the power amplifier section can be overdriven to taste and the musician is able to accurately produce both overdriven and undistorted amplifier tones at many different listening levels.

### CROSS-REFERENCE TO RELATED APPLICATIONS

This application is claiming the benefits of my provisional patent application titled “Guitar Amplifier with Volume Control and tiltable Loudspeaker”, appl. # 60/242,228 filed Oct. 23, 2000.

### TECHNICAL FIELD

This invention relates in general to audio amplifiers with loudspeaker arrangements, and more particularly, to musical instrument amplifiers such as guitar amplifiers.

### BACKGROUND OF INVENTION

Musical instrument amplifiers were actually designed to merely amplify the sound of an electrified musical instrument, such as a guitar or other instrument, and provide basic control over the tonality of the music being played. With the introduction of rock and roll, however, volume requirements exceeded power availability and, at these higher volume levels, the amplifiers produced an overdriven or distorted sound that soon became very popular. Technically, the guitar amplifier is a poor example of vacuum tube amplifier design, but the sound of a guitar playing through such an amplifier and speaker at full level actually became not just the trademark of a whole new style in music, but in essence defined a new form of musical instrument. Rather than simply a means for providing increased loudness for entertaining large audiences, those overdriven amplifiers and associated output transducers provide a reed-like sound which can be finely controlled and shaded into a variety of musical textures by the skilled guitarist. This type of guitar sound has now been widely used in popular music for about forty years and has become indispensable in modern music.

Unfortunately the one essential problem that musicians encounter is achieving this special sound at lower volume levels. Since this sound results from the amplifier being overdriven (i.e., at maximum volume), it cannot be created using conventional amplifiers at lower volume levels. Often, this makes it difficult to provide both the desired tonality for the music being played and the appropriate listening level for the particular setting in which the music is being played. Thus, for instance, an amplifier may produce one guitar sound at the limits of its power capabilities, but for a particular performance the volume requirements may be much less, and turning the amplifier down will yield a completely different tone.

Today the market may be filled with a variety of guitar amplifier designs, but still the particular sound of an overdriven tube-amplifier of simple construction is state of the art and therefore extremely popular. Thus the prior art shows many attempts to provide effective volume control for eventually overdriven guitar amplifiers but has yet not come up with an appropriate technology so far.

One first approach to solving this problem was to add master volume control. This essentially allowed the musician to turn up the pre-amplifier section to the desired overdrive level and regulate the amount of signal that went to the power amplifier section. Yet this design did not provide enough dynamic overdrive and proved not to be sensitive to the guitarist's touch. The desired sound could not be achieved without an overdriven power-amp section, which led back to the lack of adequate volume-control. Several amplifier engineers have attacked this particular problem throughout the years in different ways.

U.S. Pat. No. 4,286,492 by Claret shows the approach to provide desirable distortion from an amplifier through variable control of the “clipping point” of the power output stage of the amplifier. U.S. Pat. No. 5,091,700 by Smith shows a specially modified power transformer and AC mains switching device which are designed to have the amplifier supplied with a reduced AC current, approximately 25 percent beyond the regular rating. U.S. Pat. No. 4,143,245 and 4,363,934 by Scholz show the approach to control the output volume of an overdriven amp by coupling a resistive load in-between the amplifiers output and the loudspeaker, driving the speaker with only a portion of the amplifier output. U.S. Pat. No. 5,635,872 and 5,909,145 by Zimmermann feature a control subsystem for controlling sag in the power supply signal of an amplifier, whereby the circuit controls the decrease in the average voltage level of the power supply signal occurring when the current drawn from the power supply increases. U.S. Pat. No. 6,111,961 by Hedrick and Lamarra shows a tube amplifier with an additional amplifier stage coupled in-between the pre-amp section and the actual power-amp. A minimized artificial output stage with audio power tubes and a dummy load is added to the circuit in order to reproduce the complex distortion of an overdriven power amp at a preliminary stage of amplification. The actual power amp just serves to provide appropriate output volume and thus the arrangement is more or less a simulation, because it does not supply the necessary dynamic response of the signal.

None of the above mentioned approaches have so far led to satisfying results, because any attempt to achieve this reed-like sound at low volumes by altering an overdriven tube-type power amp-section from its original simple design has unfortunately just produced unsatisfactory results providing diminished sound-quality. Merely the attempts of Scholz and Hedrick and Lamarra can be considered as pointing in the right direction, but have essential shortcomings.

Hedrick and Lamarra simulate a “real” power output distortion in the pre-amp section, but still have to amplify the resulting signal with the actual power-amp section. Thus the dynamic response is diminished and the resulting sound can't be compared to what the player is used to when playing a fully overdriven tube amp of a simple design. Also it is obvious that the cost of building such an amplifier are immense and restrict players to either buy just one particular product or have their own amplifiers rebuilt to eventually benefit from adding yet another amplifying stage.

Scholz resistively loads any kind of eventually overdriven guitar amplifier with resistive impedances to control the amount of power being applied to the loudspeaker. This approach provides the player with the necessary dynamic response, but has an essential shortcoming. With the sole use of resistive impedances in such a network only, the speaker acts as a low-pass due to its increasing impedance with higher frequent ac signals, such as an amplified guitar tone. Especially the high-frequent portions of the guitar signal rather pass the applied resistors towards ground than to pass the self-induced high impedance of the speaker voice coil. This effect results in poor sound quality at lower volume levels due to the significant loss of high frequent signal-portions towards ground. While his U.S. Pat. No. 4,143,245 still features a large potentiometer and produces mismatching of impedances between the amplifiers output transformer and the connected loudspeaker, his U.S. Pat. No. 4,363,934 shows a resistive ladder network that maintains the input impedance to the control network approximately at a desired predetermined impedance. Both units not only diminish the proportional quality of high-frequent signal portions but also excessively emit heat in the controlling elements. Eventually the ladder network circuit proved to be too large to be built into a conventional amplifiers chassis and its volume control knob just allows switching in-between raw increments of approximately 3dB power output reduction, which is an essential drawback for a creative player who needs to adjust the volume more precisely.

Also, various attempts have been made to either analog or digitally simulate the harmonic distortion characteristics of a simple tube amplifier being driven into overload. But digital and analog simulation can by far not reproduce the full texture of the desired sound and the dynamic response requested by the player.

It is therefore an important task to provide a musician's amplifier that can create this desired overdriven sound and is controllable in its output volume without the above discussed shortcomings. The resulting tone should not be altered in its quality of harmonic distortion, range of frequency and dynamic response at any volume level.

### SUMMARY OF THE INVENTION

This invention relates to an electronic amplification system for musical instruments and, more particularly, relates to a classic tube type guitar amplifier. Such an amplifier produces an electrical output signal having predetermined tone, timbre and/or distortion characteristics and thus provides a touch sensitive sound when driven into overload. This sound can be finely controlled and shaded into a variety of musical textures by the skilled guitarist and has now been widely used in popular music for almost forty years.

Object of the present invention is to provide an amplifier that allows the musician to achieve this sound at lower volume levels because this particularly desired sound cannot be created by using conventional amplifiers at lower volume levels. Controlling the loudspeaker volume independently of the maximum R.M.S. output power of the amp is realized without significant loss of important frequencies from the applied signal. This makes it possible to provide both the desired tonality for the music being played and the appropriate listening level for the particular setting in which the music is being played.

In accordance with the present invention, there is provided a musician's amplifier that permits the musician to produce an overdriven sound with a constant proportional quality of high frequencies and constant dynamic response over a wide range of different volume levels. The amplifier system includes preferably a preamp-section and a power amp-section, at least one loudspeaker and a volume control device in form of a novel frequency-sensitive power attenuation circuit, which is coupled between the amplifier output and the speaker. The output volume level of the system can thus be conveniently controlled, while the harmonic distortion, range of frequency and dynamic response of the signal are maintained at a constant quality. The input impedance that the amplifier-section sees does not differ substantially from a certain predetermined value comparable to a conventional guitar speaker impedance.

The volume control unit comprises a first impedance means and a second impedance means. First impedance means is preferably a fixed resistor in series with the speaker. Second impedance means is a variable frequency-sensitive impedance means having a first part in parallel with said first impedance means and a second part in parallel with the speaker, further comprising a variable controller connected to a volume selection control knob to define a frequency-sensitive impedance output node. Setting these control means will change the values of the first and second parts of said frequency-sensitive impedance in a complementary manner, so that as the first part impedance increases the second part impedance concurrently decreases and vice versa. The total impedance across the variable frequency-sensitive impedance means is maintained constant. These first and second impedance means along with the speaker impedance itself essentially form a ladder-type network with the fixed resistor coupled in series with the speaker impedance to form one side of the ladder network, and first and second part of the variable frequency-sensitive impedance means forming the other side of the ladder network. The values of the applied impedances are chosen in a way to maintain the input impedance of this frequency-sensitive volume control unit, with the speaker coupled therewith, approximately equal to a certain predetermined impedance at any selected volume level throughout the complete operational range of the circuit.

In another aspect of the invention, the frequency-sensitive power attenuation circuit can be incorporated into a loudspeaker cabinet as a passive volume control device. Such a cabinet does not necessarily have to contain any amplifier.

In another aspect of the invention, the frequency-sensitive power attenuation circuit can be incorporated into a stand-alone audio amplifier chassis as a volume control device. Such an amplifier does not necessarily have to be mounted into a cabinet that also houses a loudspeaker.

In another aspect of the invention the frequency-sensitive power attenuation circuit can be facilitated as a stand alone volume control device. Such a device can be interposed in-between an audio amplifier and accompanying speaker cabinet to provide volume control.

### DESCRIPTION OF DRAWINGS

FIG. 1 is a block diagram of the audio amplifier of the present invention

FIG. 2 is a block diagram of the audio amplifier of the present invention depicting in detail the frequency-sensitive volume control circuit of the present invention

FIG. 3 is a schematic layout of the frequency-sensitive power attenuation circuit

FIG. 4 is a diagram of input impedance versus power attenuation with an 8 Ohm and a 16 Ohm speaker

FIG. 5 is a top perspective view of the physical components of the frequency-sensitive volume control circuit as actually mounted in the amplifiers' chassis

FIG. 6a shows the frequency-sensitive volume control circuit of the present invention incorporated into a stand-alone audio amplifier chassis

FIG. 6b shows the frequency-sensitive volume control circuit of the present invention facilitated as a stand-alone volume control device

FIG. 6c shows the frequency-sensitive volume control circuit of the present invention incorporated into a loudspeaker cabinet as a passive volume control device

### DESCRIPTION OF THE INVENTION

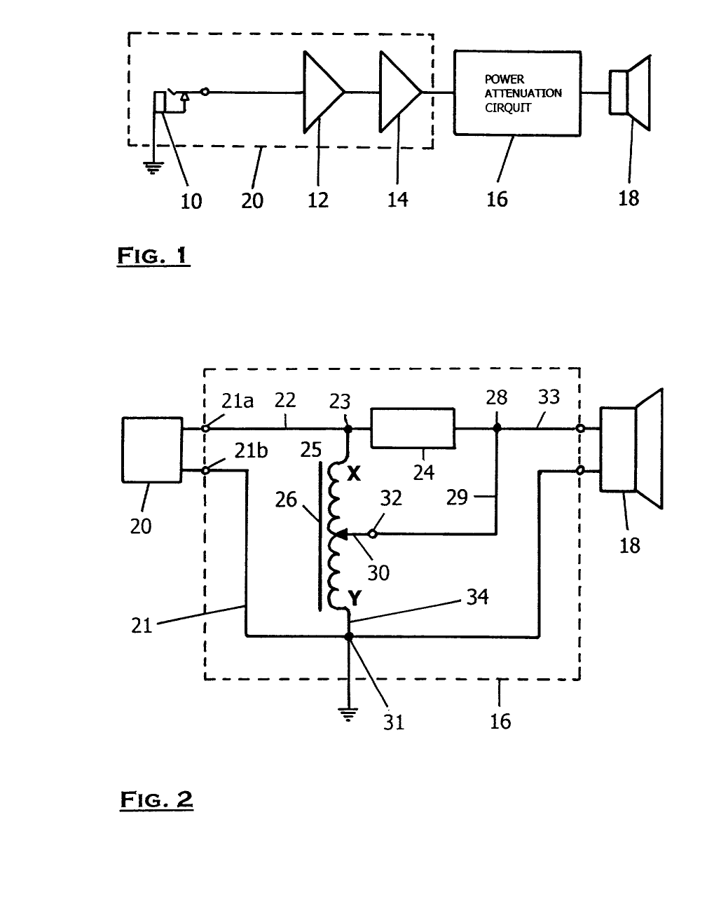

A preferred embodiment of the invention is illustrated in form of a block diagram in FIG. 1 as a musical instrument amplifier. Preferably being an all-tube type amplification system with approximately 50 watt R.M.S. output power and an associated 8 Ohm loudspeaker, the system comprises an input 10, a pre-amp section 12, a power amplifier output stage 14, a frequency-sensitive power attenuation circuit of the present invention 16 and a loudspeaker 18. The pre-amp section 12 may include a tone control network and the power amp section 14 may include an appropriate driver stage. The frequency-sensitive power attenuation circuit 16 is utilized between the power amplifier output and the loudspeaker to provide unlimited volume control.

To achieve the desired sound of an overdriven tube type guitar amplifier with a constant proportional quality of high frequencies in applied sound signals and therefore constant tonal quality at any loudspeaker volume level, including also very low levels, it is necessary to provide a volume control device in form of a frequency-sensitive power attenuation circuit. FIG. 2 of the present invention shows the amplifier of FIG. 1, depicting in detail the frequency-sensitive power attenuation circuit 16 which comprises an adjustable inductive element 26 and a fixed resistive element 24. The values of the components are chosen to maintain the input impedance to the network within a constant impedance range near a predetermined impedance at all volume levels. The fixed resistive element 24 may be a high power wire-wound resistor having a value of 22 Ohm and power rating to dissipate 100 Watt of electric energy. It is wired with conductor 33 in a series connection with the loudspeaker 18, which then is wired across the input terminals 21a and 21b with conductors 21 and 22.The adjustable inductive element 26 of the preferred embodiment of the present invention is a circular continuous tapped transformer coil (variac) as it can be found in voltage-adjustable ac power supplies. It is equipped with a variable controller 30, may have an inductance of 53,5 mH and a resistance of 6 Ohms and is wired with conductors 25 and 34 in parallel to the series connection of resistor 24 and speaker 18 across the input terminals 21a and 21b. The controller output node 32 is connected with conductor 29 to the junction point 28 of the series connection of resistor 24 and speaker 18, thus forming a variable ladder network. This frequency-sensitive power attenuation circuit can be utilized to control the loudspeaker volume by dissipating unnecessary portions of output power, without the prior art disadvantage of unproportional large loss of high frequent signal portions.

Input 10 and the amplifier stages 12 and 14 shown in FIG. 1 represent any possible embodiment of audio amplifier, which may be a classic 50 W R.M.S. tube type transformer coupled guitar amplifier with an output impedance of 4 Ohm, and are shown combined as block diagram 20 in FIG. 2. The audio signal may feature a desired amount of harmonic distortion that may result from the audio power tubes in both stages 12 and 14 being driven into a predetermined desired amount of overload. As the amplified ac signal may be undesirably powerful, it is then fed into the frequency-sensitive power attenuation circuit 16 which serves as a master volume control. The controller 30 of variac 26 can be set to an infinite number of multiple positions corresponding to an infinite amount of tap positions along the continuously tapped coil 26, thus defining two different partitions 26a and 26b of coil 26 as shown in FIG. 3. It has an output node 32 and an infinite plurality of contacts, respectfully coupled to the infinite multiple tap positions along the variac 26 to define said output node as variable frequency-sensitive output node, which is then connected to junction point 28 between the serial connection of resistor 24 and speaker 18. Because the coil 26 is continuously tapped and the controller 30 can be set to an infinite number of positions in-between the extreme settings X and Y, coil partition 26a, which is always in parallel with fixed resistor 24, and coil partition 26b, which is always in parallel with the speaker voice-coil 18a, can be altered in a complementary manner so that as the first coil-partition 26a increases, the second coil-partition 26b concurrently decreases and vice versa. The resulting variable impedances of both parallel arrangement are in a serial connection and form a frequency-sensitive ladder-type voltage divider network. because the inductive elements 26a and 26b as well as the speaker voice-coil 18a act as frequency-sensitive impedances because their ac-resistance increases with higher frequencies.

A typical guitar-signal ranges from not less than 300 Hz up to 15 kHz. The coil 26 with a nominal impedance of 6 Ohm and an inductance of 53,5 mH would react to a 300 Hz signal with a total impedance of 22,1 Ohm. At a frequency of 15 kHz it would act as a total impedance of 800 Ohm

An 8 Ohm guitar speaker typically has a voice-coil inductance of approximately 1 mH and would add a voice-coil induced impedance of just 0.3 Ohms to its value if a 300 Hz signal is applied, making a total of 8,3 Ohms. With an applied signal of 15 kHz the 8 Ohm speaker would add a voice-coil induced impedance of just another 15 Ohm, making a total of 23 Ohm.

Due to its superior ac-resistance, just a very small amount of low-frequent signal is “sunk” in the coil 26. Almost all of the signal, especially the high-frequent part, rather passes through the loudspeaker 18 or the fixed resistor 24. Therefore the amount of signal which drives the loudspeaker 18 can be controlled by utilizing the coil 26 with controller 30 as the controlling element in a frequency-sensitive ladder-type voltage divider network formed by loudspeaker 18, fixed resistor 24 and the two partitions 26a and 26b of coil 26 itself. Because of the frequency-sensitive construction of this power attenuation circuit, the sound quality of an applied guitar signal stays the same at any selected volume level and can be conveniently controlled by the player. The components may be chosen to being able to consummate up to 100 W of unnecessary electric energy. The actual amount of power to drive the speaker 18 is determined by the complementary relationship of coil partitions 26a and 26b, always leaving the remaining energy to pass the resistor 24 where it is dissipated.

If the controller 30 is set to position X, the resulting impedance of coil-partition 26a and fixed resistor 24 in parallel is minimal and the signal almost seems to bypass the resistive load 24. In reality however, coil-partition 26a has a minimal value left to be in parallel with resistor 24 and a small amount of electric energy is dissipated. The nearly 53,5 mH inductance of coil-partition 26b is much larger than the voice-coil inductance of guitar loudspeaker 18 of about 1 mH. Therefore almost no electric energy is passing through coil-portion 26b and the loudspeaker 18 receives almost full power.

If the controller 30 is set to position Y, the resulting impedance of coil-partition 26b and loudspeaker 18 in parallel is minimal and the signal almost seems to bypass the speaker. In reality however, coil-partition 26b has a minimal value left to be in parallel with the speaker 18 and a small amount of guitar signal is still passing it, thus creating a very low volume audio sound. The nearly 53,5 mH inductance of coil-partition 26a and its added nominal impedance of 6 Ohm make up to a very large impedance with increasing frequency, so that most of the electric energy has to pass resistor 24 and is dissipated.

If the controller 30 is set to any position between X and Y, the values of coil-partition 26a and 26b are determining the level of ac voltage between terminals 23 and 28 and terminal 28 and ground terminal 31. The relation of amounts of ac power which either is dissipated in resistor 24 or drives the speaker 18 can be conveniently controlled. Depending on the actual setting of controller 30, the loudspeaker 18 receives a more or less attenuated signal and the resulting superfluous heat in resistor 24 is carried off through a heat sink 42 (not shown in FIGS. 2 and 3).

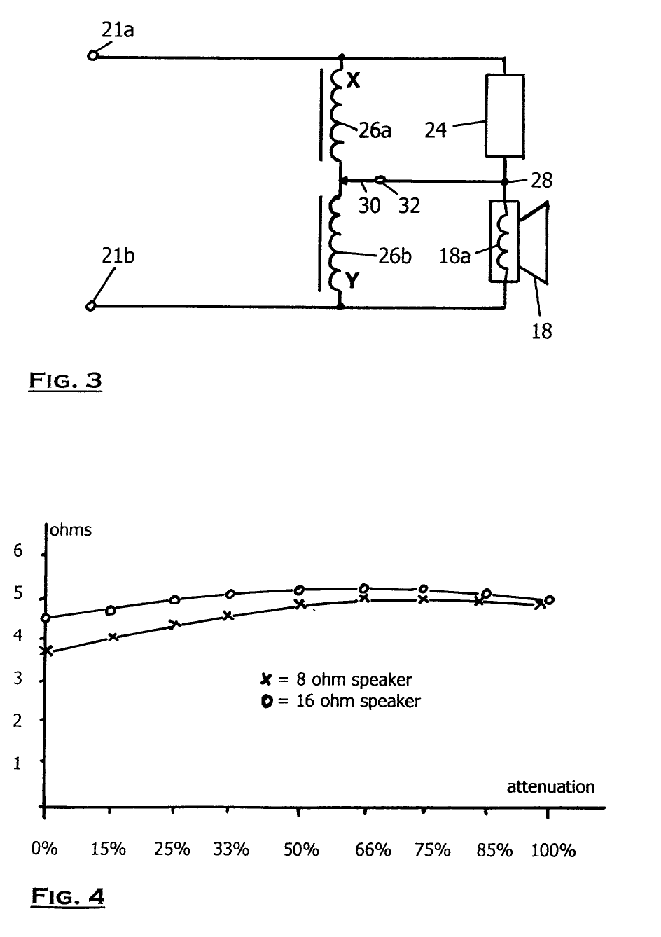

In a second preferred embodiment, the connected loudspeaker 18 may have an impedance of 16 Ohms. Thus FIG. 4 of the present invention shows a graph of volume attenuation versus input impedance for the examples of an 8 Ohm speaker and a 16 Ohm speaker. The input impedance of the frequency-sensitive power attenuation circuit 16, with a speaker coupled thereto, stays in a small range between approximately 3.7 to 4.9 Ohms in case of an 8 Ohm speaker and approximately 4.8 to 5.2 Ohms in case of a 16 Ohm speaker. The input impedance for the 8 Ohm example may be expressed by the following formula:

Z=4.3+−0.6 Ohms

and the input impedance for the 16 Ohm example may be expressed by the following formula:

Z=5.0+−0.2 Ohms.

The input impedance is calculated at settings of 0%, 15%, 25%, 33%, 50%, 66%, 75%, 85% and 100% attenuation and actually has a maximum at mid-range settings.

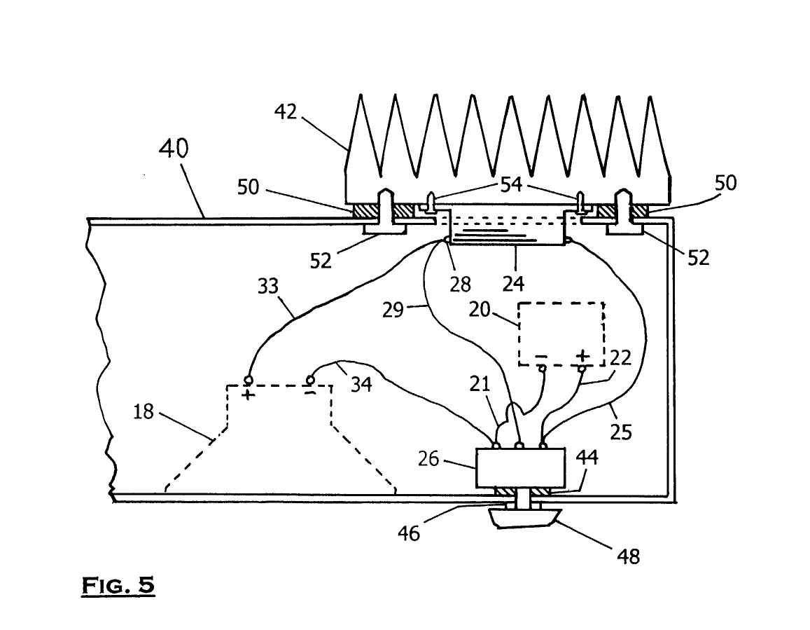

Due to better clarity, FIG. 5 shows the heat sink 42 unproportional large. Any unwanted accumulation of heat in the amplifier is avoided because fixed resistor 24 is mounted onto heat sink 42, which is mounted on distance members 50 onto the chassis 40 with screws 52. Fixed resistor 24 sits within an opening of chassis 40, mounted directly onto heat sink 42 with screws 54. In case of a very small amplifier, this part of the circuit can also be connected with elongated wires and mounted separately away from the chassis at any position within the amplifiers cabinet. The variac 26 is mounted with a nut 46 over washer 44 directly onto the front end of the chassis 40 and has a convenient volume control knob 48 on the front panel which enables the player to select the desired audio level of the amplifiers actual output signal.

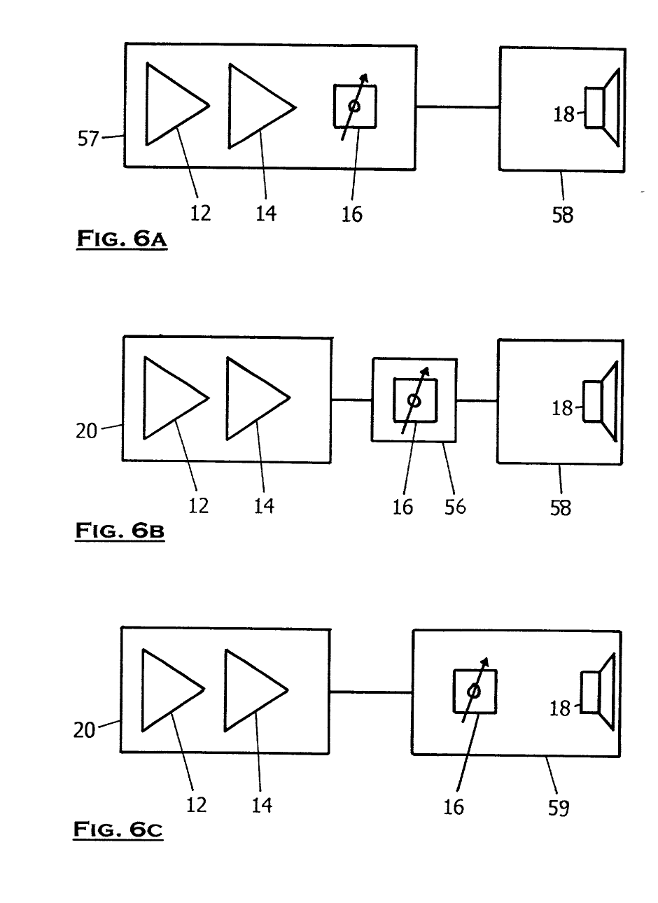

As shown in FIG. 6a, this power attenuation circuit 16 can also be incorporated into a stand-alone audio amplifier 57 and serve as master volume control for a connected loudspeaker cabinet 58.

In another preferred realization of this invention shown in FIG. 6b, the power attenuation circuit 16 would be utilized as a sole stand-alone unit 56 between the output of an audio amplifier 20 and a loudspeaker cabinet 58, thus providing a player with a conveniently connectable volume control device.

It can also be incorporated into a speaker cabinet 59 as a passive circuit to provide volume control for signals received from an amplifier 20, as shown in FIG. 6c.

Operation of the Invention

Object of the present invention is to provide an audio amplifier, which may be a 50 W R.M.S. classic tube type guitar amplifier, with an adjustable frequency-sensitive high-wattage power attenuation circuit 16 utilized between the power amplifier stage 14 and the loudspeaker 18 which permits the musician to produce an overdriven sound over a wide range of different volume levels. Said power attenuation circuit 16 comprises a high-power resistive element 24, which may be a wire-wound resistor of 22 Ohm, and a variable inductive element 26 in form of a continuous tapped transformer coil(variac). The variac has a coil inductance of 53,5 mH and a movable controller 30, which divides the coil in two variable partitions 26a and 26b. A loudspeaker 18, which may be a typical guitar speaker with a nominal impedance of 8 Ohm and a voice-coil inductance of approximately 1 mH, is connected in parallel with coil-partition 26b, whereas coil-partition 26a is always connected in parallel with said fixed resistor 24. If controller 30 is in position X, the value of coil-partition 26a is set to a minimum and the value of coil-partition 26b is set to a maximum, therefore the variac 26 is “open” and almost all electric energy is used to drive the speaker 18. By setting the controller 30 to position Y, the value of coil-partition 26a is set to a maximum and the value of coil-partition 26b is set to a minimum, therefore the variac 26 is “closed” and almost all electric energy is dissipated in resistor 24. The amount of signal power being applied to the loudspeaker 18 can be conveniently increased by moving the controller 30 continuously from position X to position Y. Coil-partitions 26a and 26b and resistor 24 in conjunction with loudspeaker 18 work as a variable frequency-sensitive voltage divider ladder network.

Normally, such a dissipation of electrical power as heat would be considered inefficient and undesirable. However, as will be appreciated by those skilled in the art, providing a high-wattage frequency-sensitive power attenuation circuit in a classic tube type guitar amplifier enables the musician to produce the real sound of an overdriven tube type amplifier over a wide range of different volume levels. Because there is no loss of high-frequent portions from the attenuated signal and no trade-off between overdrive and volume, the player can enjoy the rich harmonic content and extreme touch sensitivity of such a desired guitar tone in an unaltered sound-quality even at a very low volume setting.

Further adaptations or minor modifications within the spirit of the invention will be apparent to those skilled in the art and it will be appreciated that the present invention is not limited to the exact construction that has been described above and illustrated in the accompanying drawings. It is intended that the scope of the invention only be limited by the appended claims.

Sequence Listing

Non applicable

What is claimed is:

1. A musical instrument amplifier for use in producing an overdriven sound over a wide range of different volume levels, comprising:
a pre-amplifier section having an input and at least one amplifier stage coupled to said input, whereby said amplifier stage amplifies audio signals received through said input,
a power amplifier section having an output and at least one output stage coupled to said pre-amplifier section to receive the amplified audio signals, whereby a loudspeaker connected to said output can be operated,
a power attenuation circuit interposed between said power amplifier output and loudspeaker for controlling the volume output level from the speaker while maintaining substantially constant distortion from the amplifier, constant proportional quality of high frequencies in applied sound signals, and the input impedance of the device, with the speaker coupled therewith, within a constant impedance range near a predetermined impedance, said circuit comprising:
first impedance means coupled in series with the speaker,
second impedance including variable frequency-sensitive impedance means adapted to be manually settable to control volume output level from the speaker and having a variable frequency-sensitive impedance means output node,
means coupling said second impedance means in parallel with the series connection of the first impedance means and the speaker impedance,
and means coupling said variable frequency-sensitive impedance output node to a junction point between the series connection of the first impedance means and the speaker impedance.

2. A musical instrument amplifier as set forth in claim 1
wherein said first impedance means includes
a fixed resistor
coupled in series with the speaker impedance.

3. A musical instrument amplifier as set forth in claim 2
wherein said first impedance means further includes
a heat sink,
said fixed resistor coupled in series with the speaker impedance being mounted onto said heat sink.

4. A musical instrument amplifier as set forth in claim 1
wherein said variable frequency-sensitive second impedance means includes
a continuously tapped coil,
a volume selection control knob and
a variable controller,
said volume selection knob being directly connected to said variable controller,
said controller having infinite multiple positions corresponding to an infinite amount of tap positions along said continuously tapped coil to define said first and second parts of said variable frequency-sensitive second impedance means.

5. A musical instrument amplifier as set forth in claim 4
wherein said controller has
an infinite plurality of contacts,
respectively coupled to the infinite multiple tap positions along said continuously tapped coil, and
a contact defining said variable frequency-sensitive impedance output node,
said contact being coupled to said junction point between the series connection of the first impedance means and the speaker impedance,
whereby said first part of said variable frequency-sensitive second impedance means is being coupled in parallel with said first impedance means,
and said second part of said variable frequency-sensitive second impedance means is being coupled in parallel with the speaker.

6. A musical instrument amplifier as set forth in claim 1
wherein said first impedance means, speaker impedance and second impedance means form a ladder network with said second impedance means having complementary variable frequency-sensitive impedance sections.

7. A musical instrument amplifier as set forth in claim 1
wherein said second variable frequency-sensitive impedance means including a first part and a second part adapted to be manually settable in a complementary manner to control volume output level from the speaker,
further including control means to determine the relationship of said first and second parts,
said control means being connected to a junction point between the series connection of said first impedance means and the speaker impedance,
whereby said first part of said variable frequency-sensitive second impedance means is being coupled in parallel with said first impedance means,
and said second part of said variable frequency-sensitive second impedance means is being coupled in parallel with the speaker.

8. A volume control device for an amplifier and speaker system adapted for controlling the volume output level from the speaker while maintaining substantially constant proportional quality of high frequencies in applied sound signals and the input impedance of the device, with the speaker coupled therewith, within a constant impedance range near a predetermined impedance, said device comprising:
input terminal means for receiving an output signal from the amplifier,
first impedance means,
means coupling the first impedance means in series with the speaker impedance across the input terminal means,
second impedance including variable frequency-sensitive impedance means adapted to be manually settable to control volume output level from the speaker and having a variable frequency-sensitive impedance means output node,
means coupling said second impedance means in parallel with the series connection of the first impedance means and the speaker impedance,
and means coupling said variable frequency-sensitive impedance output node to a junction point between the series connection of the first impedance means and the speaker impedance.

9. A volume control device as set forth in claim 8
wherein said first impedance means includes
a fixed resistor
coupled in series with the speaker impedance.

10. A volume control device as set forth in claim 9
wherein said first impedance means further includes
a heat sink,
said fixed resistor coupled in series with the speaker impedance being mounted onto said heat sink.

11. A volume control device as set forth in claim 8
wherein said variable frequency-sensitive impedance means includes
a continuously tapped coil,
a variable controller and
a volume selection control knob to manually set the volume,
said control knob being directly connected to said variable controller,
said controller having infinite multiple positions corresponding to an infinite amount of tap positions along the continuously tapped coil,
thereby dividing in a complementary manner said continuously tapped coil into a first part and a second part.

12. A volume control device as set forth in claim 11
wherein said variable controller has
an infinite plurality of contacts,
respectively coupled to the infinite multiple tap positions along said continuously tapped coil, and
a contact defining the variable frequency-sensitive impedance means output node,
said contact being coupled to a junction point between the series connection of the first impedance means and the speaker impedance
whereby said first part of said continuously tapped coil is being coupled in parallel with said first impedance means, and said second part of said continuously tapped coil is being coupled in parallel with the loudspeaker.

13. A volume control device as set forth in claim 8
wherein said first impedance means, speaker impedance and second impedance means form a ladder network with said second impedance means having complementary variable frequency-sensitive impedance sections.

14. A loudspeaker cabinet for use over a wide range of different volume levels with constant sound quality, comprising:
a loudspeaker enclosure,
at least one loudspeaker,
a power attenuation circuit adapted for controlling the volume output level from the speaker while maintaining substantially constant proportional quality of high frequencies in applied sound signals and the input impedance of the circuit, with the speaker coupled therewith, within a constant impedance range near a predetermined impedance, said circuit comprising:
input terminal means for receiving an output signal from the amplifier,
first impedance means,
means coupling the first impedance means in series with the speaker impedance across the input terminal means,
second impedance including variable frequency-sensitive impedance means adapted to be manually settable to control volume output level from the speaker and having a variable frequency-sensitive impedance means output node,
means coupling said second impedance means in parallel with the series connection of the first impedance means and the speaker impedance,
and means coupling said variable frequency-sensitive impedance output node to a junction point between the series connection of the first impedance means and the speaker impedance.

15. A loudspeaker cabinet as set forth in claim 14
wherein said first impedance means includes
a fixed resistor
coupled in series with the speaker impedance.

16. A loudspeaker cabinet as set forth in claim 15
wherein said first impedance means further includes a
heat sink,
said fixed resistor coupled in series with the speaker impedance being mounted onto said heat sink.

17. A loudspeaker cabinet as set forth in claim 14
wherein said variable frequency-sensitive impedance means includes
a continuously tapped coil,
a variable controller and
a volume selection control knob to manually set the volume,
said control knob being directly connected to said variable controller,
said controller having infinite multiple positions corresponding to an infinite amount of tap positions along the continuously tapped coil,
thereby dividing in a complementary manner said continuously tapped coil into a first part and a second part.

18. A loudspeaker cabinet as set forth in claim 17
wherein said variable controller has
an infinite plurality of contacts,
respectively coupled to the infinite multiple tap positions along said continuously tapped coil, and
a contact defining the variable frequency-sensitive impedance means output node,
said contact being coupled to a junction point between the series connection of the first impedance means and the speaker impedance
whereby said first part of said continuously tapped coil is being coupled in parallel with said first impedance means, and said second part of said continuously tapped coil is being coupled in parallel with the loudspeaker.

19. A loudspeaker cabinet as set forth in claim 14
wherein said first impedance means, speaker impedance and second impedance means form a ladder network with said second impedance means having complementary variable frequency-sensitive impedance sections.
